(19) United States
(12) Patent Application Publication
(10) Pub. No.: US 2022/0098441 A1
(43) Pub. Date: Mar. 31, 2022

(54) POLISHING COMPOSITION, METHOD FOR PRODUCING THE SAME, POLISHING METHOD, AND METHOD FOR PRODUCING SUBSTRATE

(71) Applicant: FUJIMI INCORPORATED, Aichi (JP)

(72) Inventors: Yukinobu Yoshizaki, Aichi (JP); Takahito Nagano, Aichi (JP)

(21) Appl. No.: 17/462,398

(22) Filed: Aug. 31, 2021

(30) Foreign Application Priority Data
Sep. 29, 2020 (JP) 2020-163619
Jul. 19, 2021 (JP) 2021-118843

(51) Int. Cl. C09G 1/02; C09K 13/00; H01L 21/306

(52) U.S. Cl. CPC C09G 1/02; H01L 21/30625; C09K 13/00

(57) ABSTRACT

The present invention provides a means that may achieve a markedly high selectivity ratio and a markedly high effect of reducing the level difference between dissimilar materials while achieving a high polishing speed for a specific material. The present invention relates to a polishing composition containing silica on the surface of which an organic acid is immobilized, and a polyalkylene glycol, wherein the molecular weight distribution of the polyalkylene glycol in terms of polyethylene glycol by gel permeation chromatography (GPC) has two or more peaks within a predetermined molecular weight range, at least one of the peaks is derived from polyethylene glycol, and a pH of the polishing composition is 3 or more and 6 or less.

### CROSS-REFERENCE TO RELATED APPLICATION

The entire disclosure of Japanese Patent Application No. 2020-163619, filed on Sep. 29, 2020, and Japanese Patent Application No. 2021-118843, filed on Jul. 19, 2021, are incorporated herein by reference in its entirety.

### BACKGROUND

### 1. Technical Field

The present invention relates to a polishing composition, a method for producing the same, a polishing method, and a method for producing a substrate.

### 2 Description of Related Arts

In a process of producing a semiconductor device, in accordance with enhancement in performance of the semiconductor device, there have been required techniques for producing wirings with a higher density and higher integration. In such a process of producing a semiconductor device, CMP (Chemical Mechanical Polishing) is an essential process. As micronization of a semiconductor circuit progresses, flatness required for irregularities on a patterned wafer becomes higher, and thus it is required to achieve high flatness of nano-order by CMP. In order to achieve higher flatness by CMP, it is preferable that the convex part of a patterned wafer be polished at a high polishing speed whereas the concave part is not much polished.

A semiconductor wafer is composed of dissimilar materials, for example, polycrystalline silicon for forming a circuit, silicon oxide as an insulating material, and silicon nitride for protecting a surface of silicon dioxide which is not a part of a trench or a via against damages during etching. Thus, there is a problem in that a level difference remains due to a phenomenon and the like, such as dishing, in which a certain material is excessively scraped off compared to other materials because of the difference in the polishing speeds of the materials by a polishing composition. For these reasons, it is required to sufficiently eliminate the level difference in the step of polishing a patterned wafer.

As a technique for responding to the requirements, for example, in JP 2012-040671A, a polishing composition that enables polishing of an object to be polished of insufficient chemical reactivity such as silicon nitride or the like at higher speed compared to polycrystalline silicon and the like. Specifically, as such a polishing composition, disclosed is a polishing composition containing colloidal silica to which an organic acid is immobilized and of which the pH is 6 or less.

In addition, for example, in WO 2016/052281A, a polishing composition is disclosed which enables suppressing a polishing speed of polycrystalline silicon, silicon oxide, or the like while maintaining or improving a polishing speed of silicon nitride or the like and suppressing a dishing phenomenon to thereby reduce the level difference. Specifically, as such a polishing composition, there is disclosed a polishing composition containing silica on the surface of which an organic acid is immobilized and a polyoxyalkylene group-containing compound, wherein the molecular weight distribution of the weight average molecular weight of the polyoxyalkylene group-containing compound (in terms of polyethylene glycol) by gel permeation chromatography (GPC) has two or more peaks, and the pH is 7 or less.

### SUMMARY

However, in recent years, as the performance required from semiconductor devices and the like is enhanced, further enhancement in polishing performance by a polishing composition is expected. For example, a polishing composition is expected which exhibits a further higher selectivity ratio between dissimilar materials and exhibits a further higher effect of reducing the level difference on polishing a polishing composition including dissimilar materials, as compared with the polishing compositions described in JP 2012-040671A and WO 2016/052281A.

Thus, an object of the present invention is to provide a means that may achieve a markedly high selectivity ratio and a markedly high effect of reducing the level difference between dissimilar materials while achieving a high polishing speed for a specific material.

The above problem of the present invention may be solved by the following means:

a polishing composition containing:

silica on the surface of which an organic acid is immobilized; and

a polyalkylene glycol; wherein

the molecular weight distribution of the polyalkylene glycol in terms of polyethylene glycol determined by gel permeation chromatography (GPC) has two or more peaks,

at least one peak of the molecular weight distribution is a peak of which the peak top molecular weight is 1,000 or more and 6,000 or less,

at least one peak of the molecular weight distribution is a peak of which the peak top molecular weight is 100 or more and 800 or less,

the polyalkylene glycol contains polyethylene glycol,

at least one of the peaks of which the peak top molecular weight is 1,000 or more and 6,000 or less is a peak derived from polyethylene glycol, and

a pH of the polishing composition is 3 or more and 6 or less.

The above problem of the present invention may be solved also by the following means:

a method for producing a polishing composition comprising mixing silica on the surface of which an organic acid is immobilized; and

a polyalkylene glycol; wherein

the molecular weight distribution of the polyalkylene glycol in terms of polyethylene glycol determined by gel permeation chromatography (GPC) has two or more peaks,

at least one peak of the molecular weight distribution is a peak of which the peak top molecular weight is 1,000 or more and 6,000 or less,

at least one peak of the molecular weight distribution is a peak of which the peak top molecular weight is 100 or more and 800 or less,

the polyalkylene glycol contains polyethylene glycol,

at least one of the peaks of which the peak top molecular weight is 1,000 or more and 6,000 or less is a peak derived from polyethylene glycol, and

a pH of the polishing composition is 3 or more and 6 or less.

Then, the above problem of the present invention may be solved also by the following means:

a method for producing a polishing composition comprising mixing

silica on the surface of which an organic acid is immobilized;

a polyethylene glycol of which the peak top molecular weight is 1,000 or more and 6,000 or less in a molecular weight distribution in terms of polyethylene glycol by gel permeation chromatography (GPC); and

a polyalkylene glycol of which the peak top molecular weight is 100 or more and 800 or less in a molecular weight distribution in terms of polyethylene glycol by gel permeation chromatography (GPC); wherein

a pH of the polishing composition is 3 or more and 6 or less.

### DETAILED DESCRIPTION

Hereinafter, embodiments of the present invention will be described. Note that the present invention is not limited only to the following embodiments. In the present description, “X to Y” indicating a range means “X or more and Y or less”. In addition, unless otherwise specified, operations and measurements of physical properties and the like are performed under conditions of room temperature (in a range of 20° C. or more and 25° C. or less)/relative humidity of 40% RH or more and 50% RH or less.

<Polishing Composition>

One aspect of the present invention relates to a polishing composition containing silica on the surface of which an organic acid is immobilized and a polyalkylene glycol, wherein the molecular weight distribution of the polyalkylene glycol in terms of polyethylene glycol determined by gel permeation chromatography (GPC) has two or more peaks, at least one peak of the molecular weight distribution is a peak of which the peak top molecular weight is 1,000 or more and 6,000 or less, at least one peak of the molecular weight distribution is a peak of which the peak top molecular weight is 100 or more and 800 or less, the polyalkylene glycol contains polyethylene glycol, at least one of the peaks of which the peak top molecular weight is 1,000 or more and 6,000 or less is a peak derived from polyethylene glycol, and a pH of the polishing composition is 3 or more and 6 or less. According to the present aspect, there may be provided a means that may achieve a markedly high selectivity ratio and a markedly high effect of reducing the level difference between dissimilar materials while achieving a high polishing speed for a specific material.

According to such a polishing composition, there may be provided a means that may achieve a markedly high selectivity ratio and a markedly high effect of reducing the level difference between dissimilar materials while achieving a high polishing speed for a specific material.

In particular, in one embodiment of the present invention, in an object to be polished containing a material having a silicon-nitrogen bond such as silicon nitride or the like, and at least one of a material having a silicon-oxygen bond such as silicon oxide (SiN) or the like and a material having a silicon-silicon bond such as polycrystalline silicon (polysilicon, Poly-Si) or the like, the effect of the present invention is more markedly exhibited. More specifically, the polishing speed of the material having a silicon-nitrogen bond further increases. In one embodiment of the present invention, the ratio of the polishing speed of the material having a silicon-nitrogen bond to the polishing speed of the material having a silicon-oxygen bond (the selectivity ratio of the material having a silicon-nitrogen bond to the material having a silicon-oxygen bond) and the ratio of the polishing speed of the material having a silicon-nitrogen bond to the material having a silicon-silicon bond (the selectivity ratio of the material having a silicon-nitrogen bond to the material having a silicon-silicon bond) further increase. In one embodiment of the present invention, the effect of reducing the level difference of an object to be polished containing a material having a silicon-nitrogen bond such as silicon nitride or the like and a material having a silicon-oxygen bond such as silicon oxide or the like is further enhanced. In one embodiment of the present invention, the effect of reducing the level difference of the object to be polished containing a material having a silicon-nitrogen bond such as silicon nitride or the like and a material having a silicon-silicon bond such as polycrystalline silicon or the like is further enhanced.

The detailed reason why the present invention may achieve a markedly high selectivity ratio and a markedly high effect of reducing the level difference between dissimilar materials while achieving a high polishing speed for a specific material is unknown, but it is presumed that the present invention is based on the following mechanism.

The zeta potential of silica on the surface of which an organic acid is immobilized is negative, and its absolute value also becomes large. In addition, among the materials contained in the object to be polished, there exists a material of which the zeta potential becomes positive at a pH of 6 or less. Thus, when the pH of the polishing composition is 6 or less, the silica on the surface of which an organic acid is immobilized in the polishing composition and the material of which the zeta potential becomes positive in this pH range do not electrically repel each other but rather attract each other. In addition, the silica on the surface of which an organic acid is immobilized has a functional group derived from the organic acid, which is a functional group other than a hydroxy group. This functional group derived from the organic acid and a polyalkylene glycol do not interact, and the hydrophilicity inherently possessed by the silica is easily exhibited. Furthermore, under acidic conditions, since the zeta potential of the silica on the surface of which an organic acid is immobilized is large, electrical repulsion between the silicas on the surface of which an organic acid is immobilized occurs, and the dispersion stability of the silica on the surface of which an organic acid is immobilized increases. From these, in the polishing composition of which the pH is 6 or less, by use of the silica on the surface of which an organic acid is immobilized as abrasive grains, a high polishing speed for a material of which the zeta potential in this pH range becomes positive is to be obtained. Note that, as the material of which the zeta potential becomes positive in a pH range of 6 or less, for example, a material having a silicon-nitrogen bond such as silicon nitride or the like is mentioned.

In addition, a polyalkylene glycol adsorb onto the surface of the object to be polished by an action such as hydrogen bonding and the like. The polyalkylene glycol then acts to protect the surface of the object to be polished from the mechanical action by the abrasive grains. Here, the ease of adsorption of the polyalkylene glycol varies depending on the type of the object to be polished. From this, the polishing speed by the polishing composition and the selectivity ratio between dissimilar materials can be controlled in accordance with selection of the type of the object to be polished, the type of the polyalkylene glycol in the polishing composition, a combination thereof, and the like. Furthermore, by allowing a polyalkylene glycol of which the molecular weight distribution has two or more peaks to be contained in the polishing composition, a component having a smaller molecular weight further adsorbs so as to fill a gap into which a component having a larger molecular weight has adsorbed. As a result, a denser protective film is formed on the surface of the object to be polished, and the effect of reducing the level difference is further enhanced.

Then, by setting the pH range of the polishing composition containing silica on the surface of which an organic acid is immobilized and a polyalkylene glycol to 3 or more and 6 or less, it is possible to significantly enhance the selectivity ratio between dissimilar materials related to a combination of specific materials, for example, the selectivity ratio of a material having a silicon-nitrogen bond to a material having a silicon-oxygen bond.

However, the present inventors, in their studies, have found that the effect of suppressing the polishing speed for a specific material, for example, a material having a silicon-silicon bond such as polycrystalline silicon or the like may decrease more in such a pH range than in other pH ranges. This indicates that the effect of enhancing the selectivity ratio among other dissimilar materials, for example, the selectivity ratio of a material having a silicon-nitrogen bond such as silicon nitride or the like to a material having a silicon-silicon bond such as polycrystalline silicon or the like may become smaller than that in other pH ranges.

The present inventors thus have further proceeded with the studies. As a result, the present inventors have found that a decrease in the effect of suppressing the polishing speed for a specific material in this pH range is eliminated by a polyalkylene glycol containing a specific component and having a specific molecular weight distribution, and have completed the present invention. That is, in the present invention, employed is a polishing composition that contains silica on the surface of which an organic acid is immobilized and a polyalkylene glycol containing a specific component and having a specific molecular weight distribution, wherein the pH range of the polishing composition is 3 or more and 6 or less. By using such a polishing composition, a markedly high selectivity ratio and a markedly high effect of reducing the level difference can be obtained between dissimilar materials according to a wide combination. The reason for this is considered to be that, in this pH range, attractive force, repulsive force, adsorption, desorption, and the like are optimized among each material contained in the object to be polished, silica on the surface of which an organic acid is immobilized, and a polyalkylene glycol in the polishing composition. Then, this is considered to be because the selectivity ratio and the effect of reducing the level difference between dissimilar materials are markedly enhanced due to the synergistic effect of these.

Note that the above mechanism is based on a presumption, and its correctness does not affect the technical scope of the present invention.

Hereinafter, each component that may be contained in the polishing composition, each raw material to be used for production of the polishing composition, the physical properties and characteristics of the polishing composition, the object to be polished, and the like will be described.

(Silica on the Surface of which an Organic Acid is Immobilized)

The polishing composition according to an embodiment of the present invention contains silica on the surface of which an organic acid is immobilized. Also in a method for producing a polishing composition according to an embodiment of the present invention, silica on the surface of which an organic acid is immobilized is employed as a raw material. “Silica on the surface of which an organic acid is immobilized” is silica onto the surface of which an organic acid is chemically bonded, which silica is used as abrasive grains.

In the silica of the surface of which an organic acid is immobilized, as silica before immobilization of the organic acid, for example, fumed silica, colloidal silica, and the like are mentioned, but are not particularly limited thereto. Among these, colloidal silica is preferable. In addition, in the silica on the surface of which an organic acid is immobilized, a method for producing silica before immobilization of the organic acid is not particularly limited. However, from the viewpoint that production with high purity is enabled and the effects of the present invention are further enhanced, the method for producing silica before immobilization of the organic acid is preferably a sodium silicate method or a sol gel method (sol-gel method), and more preferably a sol gel method. That is, as the silica before immobilization of the organic acid, colloidal silica produced by a sol gel method or a sodium silicate method (e.g., at least one of colloidal silica produced by a sol gel method and colloidal silica produced by a sodium silicate method) is preferred, and colloidal silica produced by a sol-gel method is more preferred.

In the silica on the surface of which an organic acid is immobilized, as the organic acid, for example, sulfonic acid, carboxylic acid, phosphoric acid, and the like are mentioned, but are not particularly limited thereto. Among these, sulfonic acid or carboxylic acid is preferred, and sulfonic acid is more preferred. Note that on the surface of which an organic acid is immobilized, an acidic group (e.g., a sulfo group, a carboxyl group, a phosphate group, or the like.) derived from the above organic acid is immobilized by covalent bonding (in some cases, via a linker structure).

As the silica on the surface of which an organic acid is immobilized, a synthetic product may be used, or a commercially available product may be used. In addition, the silica on the surface of which an organic acid is immobilized may be used singly or two or more types of such silicas may be used in admixture.

A method for introducing the organic acid onto the silica surface is not particularly limited, and, for example, a method in which the organic acid is introduced onto the silica surface in a state of a mercapto group, an alkyl group, or the like, and then oxidized into a sulfonic acid or a carboxylic acid is mentioned. Also, a method in which an acidic group derived from the organic acid, in a state of being bonded to a protective group, is introduced onto the silica surface and then, the protective group is cause to leave is mentioned. In addition, it is preferable that a compound to be used on introducing the organic acid onto the silica surface have at least one functional group that may become an organic acid group and further contain a functional group to be used for bonding to a hydroxyl group on the silica surface, a functional group to be introduced for controlling hydrophobicity or hydrophilicity, a functional group to be introduced for controlling steric bulkiness, and the like.

As a specific method for synthesizing silica on the surface of which an organic acid is immobilized, if a sulfonic acid, which is a kind of organic acid, is immobilized on the surface of the silica, the immobilization can be conducted by, for example, the method described in “Sulfonic acid-functionalized silica through quantitative oxidation of thiol groups”, Chem. Commun. 246-247 (2003). Specifically, a silane coupling agent having a thiol group such as 3-mercaptopropyltrimethoxysilane or the like is coupled to silica, and then the thiol group is oxidized with hydrogen peroxide, whereby silica on the surface of which a sulfonic acid is immobilized can be obtained. Alternatively, if a carboxylic acid is immobilized on the surface of silica, the immobilization can be conducted, for example, by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, it is possible to obtain silica on the surface of which a carboxylic acid is immobilized by coupling a silane coupling agent containing a photoreactive 2-nitrobenzyl ester to silica and then irradiating the silica with light.

The average primary particle size of the silica on the surface of which an organic acid is immobilized in the polishing composition is, but not particularly limited to, preferably 5 nm or more, more preferably 7 nm or more, and still more preferably 10 nm or more. In addition, the average primary particle size of the silica on the surface of which an organic acid is immobilized in the polishing composition is preferably nm or less, more preferably 45 nm or less, and still more preferably 40 nm or less. Within these ranges, the polishing speed of a specific material by the polishing composition is further enhanced, and the selectivity ratio between dissimilar materials is further enhanced. In addition, the effect of reducing the level difference is further enhanced. Therefore, an example of a preferable average primary particle size of silica on the surface of which an organic acid is immobilized is 10 nm or more and 50 nm or less. Note that the value of the average primary particle size of the silica on the surface of which an organic acid is immobilized can be calculated, for example, based on the specific surface area of the silica on the surface of which an organic acid is immobilized as measured by the BET method.

The average secondary particle size of the silica on the surface of which an organic acid is immobilized in the polishing composition is, but not particularly limited to, preferably 10 nm or more, more preferably 15 nm or more, and still more preferably 20 nm or more. In addition, the average secondary particle size of the silica on the surface of which an organic acid is immobilized in the polishing composition is, but not particularly limited to, preferably 150 nm or less, more preferably 100 nm or less, and still more preferably 80 nm or less. Within these ranges, the polishing speed of a specific material by the polishing composition is further enhanced, and the selectivity ratio between dissimilar materials is further enhanced. In addition, the effect of reducing the level difference is further enhanced. Therefore, an example of a preferable average secondary particle size of silica on the surface of which an organic acid is immobilized is 20 nm or more and 100 nm or less. Note that the value of the average secondary particle size of the silica on the surface of which an organic acid is immobilized can be calculated based on, for example, a light scattering method measurement using laser light.

The degree of association of the silica on the surface of which an organic acid is immobilized in the polishing composition is, but not particularly limited to, preferably 1 or more, more preferably 2 or more, and still more preferably 2.5 or more. In addition, the degree of association of the silica on the surface of which an organic acid is immobilized in the polishing composition is preferably 10 or less, more preferably 8 or less, and still more preferably 5 or less. Within these ranges, the polishing speed of a specific material by the polishing composition is further enhanced, and the selectivity ratio between dissimilar materials is further enhanced. In addition, the effect of reducing the level difference is further enhanced. Note that the degree of association of the silica on the surface of which an organic acid is immobilized can be calculated by dividing the above average secondary particle size by the above average primary particle size.

The zeta potential of the silica on the surface of which an organic acid is immobilized in the polishing composition is preferably a negative (minus) value, and is preferably −5 mV or less, more preferably −10 mV or less, and still more preferably −15 mV or less. Within these ranges, aggregation of silica is less likely to occur. In addition, the zeta potential of the silica on the surface of which an organic acid is immobilized in the polishing composition is preferably −70 mV or more, more preferably −60 mV or more, and still more preferably −50 mV or more. Within these ranges, the abrasive grains are less likely to adhere onto an object to be polished. Note that the zeta potential of the silica on the surface of which an organic acid is immobilized can be specifically measured by the method described in Examples.

The shapes of the primary particles and the secondary particles of the silica on the surface of which an organic acid is immobilized are not particularly limited, and each may be spherical or non-spherical. Among these, the shape of the secondary particle is preferably a cocoon shape, or a chain shape, a branched shape, or the like, which is a shape further deformed than the cocoon shape, and more preferably a cocoon shape.

The content (amount to be added) of the silica on the surface of which an organic acid is immobilized in the polishing composition is, but not particularly limited to, preferably 0.001 mass % or more, more preferably 0.01 mass % or more, and still more preferably 0.1 mass % or more. Within these ranges, the polishing speed of an object to be polished by the polishing composition is further enhanced. In addition, the content of the silica on the surface of which an organic acid is immobilized in the polishing composition is preferably 10 mass % or less, more preferably 8 mass % or less, and still more preferably 5 mass % or less. Within these ranges, polishing of a specific material by the polishing composition is further suppressed, and the selectivity ratio between dissimilar materials is further enhanced.

In the polishing composition according to an embodiment of the present invention, it is essential to use silica on the surface of which an organic acid is immobilized as abrasive grains, but in some cases, other abrasive grains such as silica on the surface of which no organic acid is immobilized, or the like may be used in combination. However, the content ratio of the silica on the surface of which an organic acid is immobilized based on the entire abrasive grains is, but not particularly limited to, preferably 50 mass % or more, more preferably 80 mass % or more, still more preferably 90 mass % or more, particularly preferably mass % or more, and most preferably 100 mass % in terms of mass.

(Polyalkylene Glycol)

The polishing composition according to an embodiment of the present invention contains a polyalkylene glycol. Also, in the method for producing the polishing composition according to an embodiment of the present invention, a polyalkylene glycol is used as a raw material.

It is preferable that the molecular weight distribution of the polyalkylene glycol in terms of polyethylene glycol by gel permeation chromatography (GPC) have two or more peaks. Here, “having two or more peaks” means that the chart of the molecular weight distribution of the polyalkylene glycol by GPC (differential molecular weight distribution curve) has two or more maximal values. Typically, as described in the section of the method for producing the polishing composition described below, for example, by producing a polishing composition using two or more types of polyalkylene glycols different in the peak top molecular weight of the molecular weight distribution in terms of polyethylene glycol by GPC, it is possible to obtain a composition satisfying the condition of “having two or more peaks” as described above. Here, it is preferable that at least one peak of the molecular weight distribution be a peak of which the peak top molecular weight is 1,000 or more and 6,000 or less and at least one peak of the molecular weight distribution be a peak of which the peak top molecular weight is 100 or more and 800 or less. Then, it is preferable that the polyalkylene glycol contain polyethylene glycol and at least one of the peaks of which the peak top molecular weight is 1,000 or more and 6,000 or less be a peak derived from polyethylene glycol.

Here, in the molecular weight distribution of the polyalkylene glycol in terms of polyethylene glycol by GPC, it is preferable that at least one of peaks of which the peak top molecular weight is 100 or more and 800 or less be a peak derived from polyethylene glycol. It is preferable that the polyalkylene glycol further contain polypropylene glycol or polybutylene glycol, and at least one of peaks of which the peak top molecular weight is 100 or more and 800 or less be a peak derived from polypropylene glycol or polybutylene glycol. It is particularly preferable that the polyalkylene glycol contained in the polishing composition according to an embodiment of the present invention be polyethylene glycol only and that all the peaks be peaks derived from polyethylene glycol.

The number of peaks of the molecular weight distribution of the polyalkylene glycol in terms of polyethylene glycol by GPC is not particularly limited as long as it is 2 or more, but is preferably 2 or more and 10 or less, more preferably 2 or 3, and still more preferably 3. Additionally, the number of peaks of which the peak top molecular weight is 1,000 or more and 6,000 or less in the molecular weight distribution of the polyalkylene glycol in terms of polyethylene glycol by GPC is not particularly limited as long as it is 1 or more, but is preferably 1 or more and 5 or less, more preferably 1 or 2, and still more preferably 1. Then, the number of peaks of which the peak top molecular weight is 100 or more and 800 or less in the molecular weight distribution of the polyalkylene glycol in terms of polyethylene glycol by GPC is not particularly limited as long as it is 1 or more, but is preferably 1 or more and 5 or less, more preferably 1 or 2, and still more preferably 2. Within these ranges, the dispersion state of polyethylene glycol becomes better. In addition, more uniform and denser adsorption to the object to be polished becomes possible, and better control of the level difference shape, which cannot be achieved by a single peak, becomes possible.

At least one of the peaks of which the peak top molecular weight is 1,000 or more and 6,000 or less in the molecular weight distribution of the polyalkylene glycol in terms of polyethylene glycol by GPC is, but not particularly limited to, preferably has a peak top molecular weight of 1,100 or more and 5,000 or less, and more preferably has a peak top molecular weight of 1,200 or more and 4,000 or less. Within these ranges, the selectivity ratio is more enhanced between dissimilar materials. In addition, the effect of reducing the level difference is further enhanced. Then, when the polyalkylene glycol has a plurality of peaks of which the peak top molecular weight is 1,000 or more and 6,000 or less, it is preferable that all the peaks each have a peak top molecular weight within the above range. At this time, the selectivity ratio is more enhanced between dissimilar materials. In addition, the effect of reducing the level difference is further enhanced.

At least one of the peaks of which the peak top molecular weight is 100 or more and 800 or less in the molecular weight distribution of the polyalkylene glycol in terms of polyethylene glycol by GPC is, but not particularly limited to, more preferably has a peak top molecular weight of 150 or more and 700 or less, and still more preferably has a peak top molecular weight of 200 or more and 600 or less. Within this range, the selectivity ratio is more enhanced between dissimilar materials. In addition, the effect of reducing the level difference is further enhanced. Then, when the polyalkylene glycol has a plurality of peaks of which the peak top molecular weight is 100 or more and 800 or less, it is preferable that all the peaks be peaks be peaks within the above range. At this time, the selectivity ratio is more enhanced between dissimilar materials. In addition, the effect of reducing the level difference is further enhanced.

When two or more types of polyalkylene glycols are used as the raw material, as polyalkylene glycols as the raw material, for example, polyalkylene glycols having a peak top molecular weight in the same range as the preferable range of each peak described above and the like are mentioned, but are not particularly limited thereto.

The molecular weight distribution of the polyalkylene glycol in terms of polyethylene glycol by GPC and the peak top molecular weight can be specifically measured by the methods described in Examples. The number average molecular weight and the weight average molecular weight can also be measured by the same methods.

The polyalkylene glycol contained in the polishing composition may be composed of a commercially available product or may be composed of a synthetic product. The polyalkylene glycol contained in the polishing composition may be composed of a single type of polyalkylene glycol or may be composed of two or more types of polyalkylene glycols. Among these, the polyalkylene glycol is preferably composed of a single type of polyalkylene glycol.

As the type of the polyalkylene glycol, polyalkylene glycol and the like such as polyethylene glycol, polypropylene glycol, polybutylene glycol, and a copolymer of at least two or more selected from the group consisting of ethylene glycol, propylene glycol and glycol, and the like, are mentioned, but are not particularly limited thereto. Among these, polyethylene glycol and polypropylene glycol are preferable, and polyethylene glycol is more preferable.

Note that, when two or more types of polyalkylene glycols are used as the raw material, as the raw material polyalkylene glycols, for example, polyalkylene glycols and the like such as polyethylene glycol, polypropylene glycol, polybutylene glycol, and the like are mentioned, but are not particularly limited thereto. As a commercial product, for example, polyethylene glycol 200; 600; 1,000; 1,540; 2,000; 4,000; 6,000; 8,000; 20,000 (all manufactured by FUJIFILM Wako Pure Chemical Corporation); Polyethylene glycol 10,000 (manufactured by Alfa Aesar); polypropylene glycol, diol type, 400 (manufactured by FUJIFILM Wako Pure Chemical Corporation); and the like are mentioned, but are not particularly limited thereto. In addition, block polymers and the like typified by PRONON (registered trademark) series such as PRONON (registered trademark) 102, PRONON (registered trademark) 201, and the like (all manufactured by NOF CORPORATION) are mentioned. Among these, polyethylene glycol and polypropylene glycol are preferable, and polyethylene glycol is more preferable.

The content (amount to be added) of the polyalkylene glycol in the polishing composition is, but not particularly limited to, preferably 0.001 g/L or more, more preferably 0.01 g/L or more, and still more preferably 0.1 g/L or more. In addition, the content of the polyalkylene glycol in the polishing composition is preferably 100 g/L or less, more preferably 10 g/L or less, and still more preferably 5 g/L or less. Within these ranges, the selectivity ratio between dissimilar materials is more enhanced. In addition, the effect of reducing the level difference is further enhanced.

When a polyethylene glycol of which the peak top molecular weight is 1,000 or more and 6,000 or less and a polyalkylene glycol of which the peak top molecular weight is 100 or more and 800 or less, in the molecular weight distribution in terms of polyethylene glycol by gel permeation chromatography (GPC), are used as raw materials, the proportion of the amount of the polyethylene glycol of which the peak top molecular weight is 1,000 or more and 6,000 or less to be added based on the sum of the amounts of these to be added is, but not particularly limited to, preferably 10 mass % or more, more preferably 20 mass % or more, still more preferably 40 mass % or more, even more preferably 70 mass % or more, and particularly preferably 75 mass % or more. In addition, the proportion of the amount of the polyethylene glycol of which the peak top molecular weight is 1,000 or more and 6,000 or less to be added based on the sum of the amounts of these to be added is preferably 90 mass % or less, more preferably 85 mass % or less, and still more preferably 80 mass % or less.

(Polishing Accelerator)

It is preferable that the polishing composition according to an embodiment of the present invention contain a polishing accelerator. Also, in the method for producing a polishing composition according to an embodiment of the present invention, it is preferable to use a polishing accelerator as a raw material. The polishing accelerator acts to enhance the polishing speed of a specific material by the polishing composition. As a result, the selectivity ratio is more enhanced between dissimilar materials.

As the polishing accelerator, preferable is a compound capable of enhancing the polishing speed of a material of which the zeta potential becomes positive (a polishing accelerator for a material of which the zeta potential becomes positive) at the pH possessed by the polishing composition, but is not particularly limited thereto. In addition, it is more preferable that the polishing accelerator be a compound capable of enhancing the polishing speed of a material having a silicon-nitrogen bond such as silicon nitride or the like (a polishing accelerator for a material having a silicon-nitrogen bond, preferably a polishing accelerator for silicon nitride). Even when the positive absolute value of the zeta potential of the material to be polished is small, such a compound can realize a higher polishing speed and a high selectivity ratio in the case where silica on the surface of which an organic acid is immobilized, of which the zeta potential is negative, is used.

As the polishing accelerator for a material having a silicon-nitrogen bond such as silicon nitride, for example, N-methyl-D-glucamine, D-glucamine, N-ethyl-D-glucamine, N-propyl-D-glucamine, N-octyl-D-glucamine, N-acetyl-D-glucosamine, tris(hydroxymethyl) aminomethane, bis(2-hydroxyethyl)aminotris(hydroxymethyl) methane, N-(2-acetamide)iminodiacetic acid, N,N-di(2-hydroxyethyl) glycine, N-[tris(hydroxymethyl)methyl]glycine, hydroxyethyliminodiacetic acid, iminodiacetic acid, hydroxyethylidenediphosphonic acid (HEDP), nitrilotrismethylenephosphonic acid, phosphonobutanetricarboxylic acid, salts thereof, and the like are mentioned, but are not particularly limited thereto. Alkanolamines, amino acids, salts thereof, and the like are also mentioned. Among these, N-methyl-D-glucamine is preferable.

As the polishing accelerator, a synthetic product may be used, or a commercially available product may be used. In addition, the polishing accelerator may be used singly or two or more types of such polishing accelerator may be used in admixture.

The content (amount to be added) of the polishing accelerator in the polishing composition is, but not particularly limited to, preferably 0.01 g/L or more, more preferably 0.1 g/L or more, and still more preferably 1 g/L or more. Within these ranges, the effect of enhancing the polishing speed of a specific material by the polishing accelerator is further enhanced. In addition, the content of the polishing accelerator in the polishing composition is preferably 100 g/L or less, more preferably 50 g/L or less, and still more preferably 10 g/L or less. Within such a range, it is possible to more reduce the possibility that redeposition of the polishing accelerator occurs. In addition, it is possible to more reduce the possibility that alteration of the polishing composition occurs by the reaction between the polishing accelerator and other additives.

(Level Difference Modifier)

The polishing composition according to an embodiment of the present invention preferably contains a level difference modifier. Also, in the method for producing a polishing composition according to an embodiment of the present invention, it is preferable to use a level difference modifier as a raw material. The level difference modifier acts to reduce a level difference unintentionally generated between dissimilar materials related to a specific combination of materials and a level difference unintentionally generated between coarse and dense portions of a pattern.

As the level difference modifier, preferable is a compound that can further enhance the effect of reducing the level difference in an object to be polished that includes a material having a silicon-nitrogen bond such as silicon nitride or the like and a material having a silicon-oxygen bond such as silicon oxide or the like (preferably a level difference modifier for a material having a silicon-nitrogen bond and a material having a silicon-oxygen bond, more preferably a level difference modifier for silicon nitride and silicon oxide), but is not particularly limited thereto. In addition, it is preferable that the level difference modifier be a compound that can further enhance the effect of reducing the level difference in an object to be polished that includes a material having a silicon-nitrogen bond such as silicon nitride or the like and a material having a silicon-silicon bond such as polycrystalline silicon or the like (preferably a level difference modifier for a material having a silicon-nitrogen bond and a material having a silicon-silicon bond, more preferably a level difference modifier for silicon nitride and polycrystalline silicon).

As the level difference modifier for a material having a silicon-nitrogen bond such as silicon nitride and a material having a silicon-oxygen bond such as silicon oxide or the level difference modifier for a material having a silicon-nitrogen bond such as silicon nitride and a material having a silicon-silicon bond such as polycrystalline silicon, a compound having an aromatic ring and a sulfo group directly bonded to the aromatic ring, a salt thereof, and the like are mentioned as preferred examples, but are not particularly limited thereto. The aromatic ring may be an aromatic hydrocarbon ring or an aromatic heterocyclic ring, and may be a single ring or a ring formed by condensation of two or more rings. More specifically, it is preferable that the level difference modifier be at least one selected from the group consisting of, for example, a compound represented by the following general formula (1) and a salt thereof, a compound represented by the following general formula (2) and a salt thereof, and a (co)polymer containing a structural unit represented by the following general formula (3) and a salt thereof. In other words, it is preferable that the level difference modifier be at least one selected from the group consisting of a compound represented by the following general formula (1), a compound represented by the following general formula (2), a (co)polymer containing a structural unit represented by the following general formula (3), and salts thereof. Note that the (co)polymer denotes a generic term including a copolymer and a homopolymer.

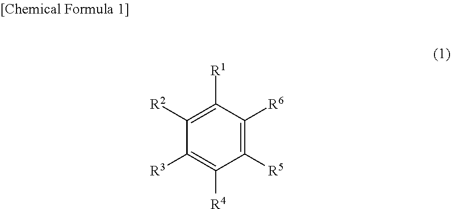

In the above general formula (1), R¹ to R⁶ are each independently a hydrogen atom, a hydroxy group, a sulfo group, an anionic group not containing a sulfo group, a cationic group, an alkoxycarbonyl group having 2 to 6 carbon atoms, or a hydrocarbon group having 1 to 10 carbon atoms, where at least one of R¹ to R⁶ is a sulfo group.

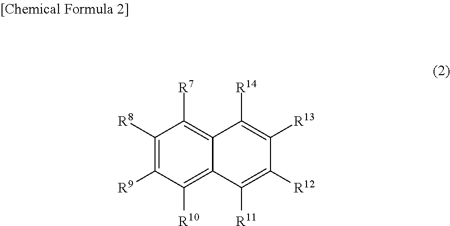

In the above general formula (2), R⁷ to R¹⁴ each independently represent a hydrogen atom, a hydroxy group, a sulfo group, an anionic group not containing a sulfo group, a cationic group, an alkoxycarbonyl group having 2 to 6 carbon atoms, or a hydrocarbon group having 1 to 10 carbon atoms, where at least one of R⁷ to R¹⁴ is a sulfo group.

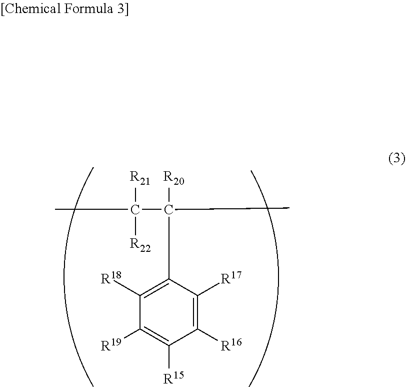

In the above general formula (3), R¹⁵ to R¹⁹ are each independently a hydrogen atom, a hydroxy group, a sulfo group, an anionic group not containing a sulfo group, a cationic group, an alkoxycarbonyl group having 2 to 6 carbon atoms, or a hydrocarbon group having 1 to 10 carbon atoms, where at least one of R′5 to R¹⁹ is a sulfo group, and R²⁰ to R²² are each independently a hydrogen atom, a hydroxy group, an anionic group not containing a sulfo group, a cationic group, an alkoxycarbonyl group having 2 to 6 carbon atoms, or a hydrocarbon group having 1 to 10 carbon atoms that is substituted with a hydroxy group, an anionic group not containing a sulfo group, a cationic group, or an alkoxycarbonyl group having 2 to 6 carbon atoms, or unsubstituted.

Note that, in the general formula (1) to the general formula (3), the anionic group means a functional group from which a counter ion is dissociated to become an anion. In addition, in the general formula (1) to the general formula (3), the cationic group means a functional group from which a counter ion is dissociated or which is bonded to a cation species generated by ionization of another ionic compound to become a cation. As the cationic group, for example, an amino group and the like are mentioned, but are not particularly limited thereto.

In the general formula (1) to the general formula (3), the amino group represents a —NH₂ group, a —NHR group, or a —NRR′ group (R and R′ each represent a substituent.). Additionally, in the general formula (1) to the general formula (3), as the alkoxycarbonyl group having 2 to 6 carbon atoms, a methoxycarbonyl group, an ethoxycarbonyl group, a n-propyloxycarbonyl group, an isopropyloxycarbonyl group, a n-butoxycarbonyl group, a sec-butoxycarbonyl group, a tert-butoxycarbonyl group, and the like are mentioned as preferred examples, but are not particularly limited thereto. In the general formula (1) to the general formula (3), as the hydrocarbon group having 1 to 10 carbon atoms, a methyl group, an ethyl group, a n-propyl group, an isopropyl group, a n-butyl group, a sec-butyl group, a tert-butyl group, and the like are mentioned as preferred example, but are not particularly limited thereto.

The copolymer containing the structural unit represented by the general formula (3) or a salt thereof may further contain a structural unit derived from another monomer. As the structural unit derived from another monomer possessed by the copolymer containing the structural unit represented by the general formula (3) or the salt thereof, structural units and the like derived from an ethylenically unsaturated monomer, a diamine, or a diepoxide are mentioned as preferred examples, but are not particularly limited thereto. Additionally, the weight average molecular weight of the (co)polymer containing the structural unit represented by the general formula (3) or a salt thereof is, but not particularly limited to, preferably 1,000 or more. Then, the weight average molecular weight of the (co)polymer containing the structural unit represented by the general formula (3) or a salt thereof is preferably 1,000,000 or less. Note that the weight average molecular weight of the (co)polymer containing the structural unit represented by the general formula (3) or a salt thereof can be determined as a value in terms of polystyrene as measured by GPC.

Among these, from the viewpoints of the effect of reducing the level difference in an object to be polished containing a material having a silicon-nitrogen bond such as silicon nitride or the like and a material having a silicon-oxygen bond such as silicon oxide or the like and the effect of reducing the level difference in an object to be polished containing a material having a silicon-nitrogen bond such as silicon nitride or the like and a material having a silicon-silicon bond such as polycrystalline silicon or the like, as the level difference reducing agent, a compound represented by the general formula (1) or a salt thereof is preferred. Additionally, it is preferred that the compound represented by the general formula (1) or a salt thereof be a compound of the general formula (1) in which R¹ is a sulfo group, and R² to R⁶ are each independently a hydrogen atom, a hydroxy group, an anionic group not containing a sulfo group, a cationic group, an alkoxycarbonyl group having 2 to 6 carbon atoms, or a hydrocarbon group having 1 to 10 carbon atoms, or a salt thereof. Then, it is more preferable that the compound represented by the general formula (1) or a salt thereof be a compound of the general formula (1) in which R¹ is a sulfo group, and R² to R⁶ are each independently a hydrogen atom, a —NH₂ group, a methyl group, an ethyl group, a n-propyl group, an isopropyl group, a n-butyl group, a sec-butyl group, or a tert-butyl group, or a salt thereof. Further, it is further preferable that the compound represented by the general formula (1) or a salt thereof be a compound in which R¹ is a sulfo group, and R² to R⁶ are each independently a hydrogen atom or a methyl group in the general formula (1), or a salt thereof.

In addition, from the viewpoints of the effect of reducing the level difference in an object to be polished containing a material having a silicon-nitrogen bond such as silicon nitride or the like and a material having a silicon-oxygen bond such as silicon oxide or the like and the effect of reducing the level difference in an object to be polished containing a material having a silicon-nitrogen bond such as silicon nitride or the like and a material having a silicon-silicon bond such as polycrystalline silicon or the like, as specific examples of the preferred level difference reducing agent, m-xylenesulfonic acid or a salt thereof, p-toluidine-2 sulfonic acid or a salt thereof, 2-naphthol-6 sulfonic acid or a salt thereof, 1-naphthalenesulfonic acid or a salt thereof, para-styrenesulfonic acid-styrene copolymer or a salt thereof, and the like are mentioned, but are not particularly limited thereto. Thus, as specific examples of the preferred level difference reducing agent, m-xylene sulfonic acid, p-toluidine-2-sulfonic acid, 2-naphthol-6 sulfonic acid, 1-naphthalene sulfonic acid, a para-styrene sulfonic acid-styrene copolymer, salts thereof, and the like are mentioned, but are not particularly limited thereto. Among these, m-xylene sulfonic acid or a salt thereof and p-toluidine-2 sulfonic acid or a salt thereof, which are a compound represented by the general formula (1) or a salt thereof, are is more preferable, m-xylene sulfonic acid or a salt thereof is still more preferable, and m-xylene sulfonic acid is particularly preferable. Thus, as more preferred specific examples, m-xylene sulfonic acid, p-toluidine-2-sulfonic acid, and salts thereof are mentioned, as further preferred specific examples, m-xylene sulfonic acid and salts thereof are mentioned, and as a particularly preferred specific example, m-xylene sulfonic acid is mentioned.

When the level difference modifier is a salt, a part or all of the sulfo group or other functional groups that may form a salt may be a salt.

As the level difference modifier, a synthetic product may be used, or a commercially available product may be used. In addition, the level difference modifier may be used singly or two or more types of such level difference modifiers may be used in admixture.

The content (amount to be added) of the level difference modifier in the polishing composition is, but not particularly limited to, preferably 0.01 g/L or more, more preferably 0.1 g/L or more, and still more preferably 1 g/L or more. Within these ranges, the effect of reducing a level difference unintentionally generated between dissimilar materials related to a specific combination of materials or a level difference unintentionally generated between coarse and dense portions of a pattern is further enhanced. In addition, the content of the level difference modifier in the polishing composition is preferably 100 g/L or less, more preferably 50 g/L or less, and still more preferably 10 g/L or less. Within such a range, it is possible to more reduce the possibility that redeposition of the level difference modifier occurs. In addition, it is possible to more reduce the possibility that alteration of the polishing composition occurs due to the reaction between the level difference modifier and other additives.

The level difference modifier may be in the state of the level difference modifier itself or in the state of a hydrate thereof during mixing on preparing the polishing composition. When the level difference modifier is mixed in its hydrate state, the content of the level difference modifier in the polishing composition represents the content calculated from the mass excluding the hydrated water.

(pH Adjusting Agent)

It is preferable that the polishing composition according to an embodiment of the present invention contains a pH adjusting agent. In the method for producing a polishing composition according to an embodiment of the present invention, it is preferable to use a pH adjusting agent as a raw material. The pH adjusting agent acts to adjust the pH of the polishing composition to a desired value by adding an appropriate amount of the pH adjusting agent to the polishing composition.

As the pH adjusting agent, a known pH adjusting agent used in the field of polishing compositions can be used, but is not particularly limited thereto. Among these, it is preferable to use a known acid, base, salt thereof, or like.

The acid as the pH adjusting agent may be, but not particularly limited to, an inorganic acid or an organic acid. As the inorganic acid, for example, carbonic acid, hydrochloric acid, nitric acid, phosphoric acid, hypophosphorous acid, phosphorous acid, phosphonic acid, sulfuric acid, boric acid, hydrofluoric acid, orthophosphoric acid, pyrophosphoric acid, polyphosphoric acid, metaphosphoric acid, hexametaphosphoric acid, and the like are mentioned, but are not limited thereto. Among these, it is preferable that the inorganic acid be nitric acid.

As the organic acid, a carboxylic acid, an organic phosphorus-based acid having a phosphonic acid group or a phosphoric acid group, a sulfonic acid, and the like are mentioned. Among these, it is preferable that the organic acid be a carboxylic acid.

The organic acid may be an organic acid having only one organic acid group in the molecule or an organic acid having two or more organic acid groups in the molecule. As the organic acid having only one organic acid group in the molecule, for example, an organic acid having only one organic acid group selected from the group consisting of a carboxy group (carboxylic acid group), a phosphonic acid group or a phosphoric acid group, and a sulfo group (sulfonic acid group) in the molecule is preferable, but is not particularly limited thereto. Specifically, for example, a monocarboxylic acid such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, hydroxyisobutyric acid, salicylic acid, and lactic acid, and the like, monosulfonic acids such as methanesulfonic acid, ethanesulfonic, acid and isethionic acid, and the like, a monovalent organic phosphoric acid-based acid, and the like, are mentioned, but are not particularly limited to. Additionally, as the organic acid having two or more organic acid groups in the molecule, preferable is, for example, an organic acid having two or more organic acid groups selected from the group consisting of a carboxy group (carboxylic acid group), a phosphonic acid group or a phosphoric acid group, and a sulfo group (sulfonic acid group) in the molecule, but is not particularly limited thereto. As specific examples thereof, for example, polyvalent carboxylic acids such as succinic acid, adipic acid, glutaric acid, pimelic acid, phthalic acid, isophthalic acid, terephthalic acid, oxalic acid, maleic acid, fumaric acid, citraconic acid, mesaconic acid, 2-pentenedioic acid, methylene succinic acid, allyl malonic acid, isopropylidene succinic acid, 2,4-hexadienedioic acid, acetylene dicarboxylic acid, citric acid, malic acid, tartaric acid, aconitic acid, itaconic acid, mellitic acid, and the like, polyvalent sulfonic acids, polyvalent organic phosphoric acid-based acids such as phytic acid, hydroxyethylidene diphosphonic acid, and the like, and the like are mentioned, but are not particularly limited to.

As specific examples of the base, for example, hydroxides of alkali metals such as potassium hydroxide and the like, ammonia, quaternary ammonium salts such as tetramethylammonium, tetraethylammonium, and the like, amines such as ethylenediamine, piperazine, and the like, and the like are mentioned, but are not particularly limited to.

Among these, the pH adjusting agent is preferably an acid, more preferably an acid having two or more acidic groups in the molecule, and still more preferably an organic acid having two or more organic acid groups in the molecule. In addition, the pH adjusting agent is even more preferably a polycarboxylic acid, particularly preferably an aliphatic polycarboxylic acid, and even more particularly preferably an unsaturated aliphatic polycarboxylic acid. Then, the pH adjusting agent is extremely preferably an unsaturated aliphatic divalent carboxylic acid and most preferably maleic acid.

The content (amount added) of the pH adjusting agent in the polishing composition is not particularly limited as long as the amount results in a pH of the polishing composition of 3 or more and 6 or less, but it is preferable to add an amount that results in a preferable pH value of the polishing composition described below.

(Dispersing Medium)

It is preferable that the polishing composition according to an embodiment of the present invention contain a dispersing medium. In the method for producing a polishing composition according to an embodiment of the present invention, it is preferable to use a dispersing medium as a raw material. The dispersing medium acts to disperse or dissolve each component.

The dispersing medium is not particularly limited, and water, an organic solvent, and the like are mentioned. As the organic solvent, it is possible to use a known organic solvent can be used without particular limitation. Among these, the dispersing medium preferably contains water, and more preferably contains only water. Furthermore, from the viewpoint of preventing the influence of the polishing composition on other components due to impurities, it is preferable to use water as pure as possible. Specifically, pure water or ultrapure water obtained by impurity ions are removed with an ion exchange resin and then foreign substances are removed through a filter or distilled water is preferable. In addition, for the purpose of controlling the dispersibility or the like of other components of the polishing composition, as a dispersing medium in addition to water, an organic solvent or the like such as acetone, acetonitrile, methanol, ethanol, isopropanol, glycerin, ethylene glycol, or propylene glycol or the like, which is an organic solvent miscible with water, may be further contained. In use of an organic solvent miscible with water in addition to water, water and the organic solvent may be mixed, and each component may be added to and dispersed or dissolved in the resulting mixed solvent. Alternatively, these organic solvents may be used without being mixed with water, and each component may be dispersed or dissolved and then mixed with water. It is possible to use these organic solvents miscible with water singly or two or more types thereof in combination.

(Other Components)

The polishing composition according to an embodiment of the present invention may further contain other known components used in the field of the polishing composition as necessary. In addition, in the method for producing a polishing composition according to an embodiment of the present invention, as a raw material, other known components used in the field of the polishing composition may be further used as necessary. As the other components, for example, a complexing agent, a metal anticorrosive, an antiseptic agent, an antifungal agent, an oxidizing agent, a reducing agent, an electrical conductivity adjusting agent, a water-soluble polymer other than the components described above, and the like are mentioned, but are not particularly limited thereto. Among these, it is preferable to contain an antiseptic agent or an antifungal agent.

As the antiseptic agent or the antifungal agent, it is possible to use an antiseptic agent or an antifungal agent known in the field of polishing compositions, but are not particularly limited thereto. Specifically, for example, isothiazoline-based antiseptic agents such as 2-methyl-4-isothiazoline-3-one and 5-chloro-2-methyl-4-isothiazoline-3 one, paraoxybenzoic acid esters, phenoxyethanol, and the like are mentioned.

(pH of Polishing Composition)

In an embodiment of the present invention, the pH of the polishing composition is 3 or more and 6 or less. When the value of pH is more than 6, the positive absolute value of the zeta potential of a material of which the zeta potential is positive becomes small, and thus it is difficult to perform polishing at a high polishing speed when silica on the surface of which an organic acid is immobilized, of which the zeta potential is negative, is used. As a result, the selectivity ratio decreases between dissimilar materials including such a material. In addition, the pH of the polishing composition is preferably 5.5 or less and more preferably 5 or less. Within these ranges, while a material of which the zeta potential is positive is polished at a sufficient polishing speed by the polishing composition, it is possible to obtain a higher selectivity ratio and a higher effect of reducing the level difference between dissimilar materials related to a wide range of combinations including this. On the other hand, when the value of pH is less than 3, the selectivity ratio between dissimilar materials decreases. For example, when a material having a silicon-oxygen bond such as silicon oxide or the like exists in the vicinity or the like of a material having a silicon-nitrogen bond such as silicon nitride or the like, on the object to be polished, it is not possible to sufficiently secure the selectivity ratio of the material having a silicon-nitrogen bond to the material having a silicon-oxygen bond. The pH of the polishing composition is preferably 3.5 or more and more preferably 4.5 or more. Within these ranges, it is possible to obtain a higher selectivity ratio and a higher effect of reducing the level difference, between dissimilar materials related to a wide range of combinations including a material of which the zeta potential is positive. Note that it is possible to measure the pH of the polishing composition by the method described in Examples. In addition, it is possible to adjust the pH of the polishing composition, for example, by the amount of a pH adjusting agent and the like to be added.

(Type of Polishing Composition)

The polishing composition in an embodiment of the present invention or the polishing composition produced by the method for producing a polishing composition according to an embodiment of the present invention may be a one-liquid type or may be a multi-liquid type including a two-liquid type. In the case of the multi-liquid type, the polishing composition in one embodiment of the present invention or the polishing composition produced by the method for producing a polishing composition according to one embodiment of the present invention may be one liquid, two or more liquids, or all of the liquids among multi liquids. In addition, the polishing composition according to an embodiment of the present invention or the polishing composition produced by the method for producing a polishing composition according to an embodiment of the present invention may be adjusted by diluting a stock solution of the polishing composition, for example, 10 times or more using a diluent such as water.

(Object to be Polished)

The object to be polished to which the polishing composition according to an aspect of the present invention, the polishing composition produced by the production method according to another aspect of the present invention described below, the polishing method according to another aspect of the present invention described below, and a method for producing a substrate according to still another aspect of the present invention described below are applied is not particularly limited, and can be applied to a known object to be polished for use the field of CMP. As the object to be polished, for example, an object to be polished containing a metal, a material having a silicon-nitrogen bond, and another material containing silicon, and the like are mentioned.

The object to be polished is preferably an object to be polished containing two or more types of materials, and more preferably an object to be polished containing (a) a material having a silicon-nitrogen bond and (b) another material containing silicon.

(a) Material Having Silicon-Nitrogen Bond

As the material having a silicon-nitrogen bond, for example, silicon nitride (SiN), silicon carbonitride (SiCN), and the like are mentioned, but are not particularly limited thereto.

(b) Another Material Containing Silicon

As another material containing silicone, silicon-containing materials other than the above-described material having a silicon-nitrogen bond wound not be particularly limited, and, for example, materials as follows are mentioned.

(b-1) Material Having Silicon-Oxygen Bond

As the material having a silicon-oxygen bond, for example, silicon oxide, BD (black diamond: SiOCH), FSG (fluorosilicate glass), HSQ (hydrogen silsesquioxane), CYCLOTENE, SiLK, MSQ (methyl silsesquioxane), and the like are mentioned, but are not particularly limited thereto. Among these, silicon oxide is preferable. Then, as the silicon oxide, silicon oxide derived from tetraethyl orthosilicate (TEOS) (herein, it is also simply referred to as “TEOS-SiO”) is particularly preferable, but is not particularly limited thereto.

(b-2) Material Having Silicon-Silicon Bond

As an object to be polished having a silicon-silicon bond, for example, polycrystalline silicon (Polysilicon, Poly-Si), amorphous silicon, monocrystalline silicon, n-type doped monocrystalline silicon, p-type doped monocrystalline silicon, Si-based alloys such as SiGe, and the like, and the like are mentioned, but are not particularly limited thereto. Among these, it is preferable that the material be polycrystalline silicon.

Therefore, it is preferable that the object to be polished to which the polishing composition according to an aspect of the present invention, the polishing composition produced by the production method according to another aspect of the present invention described below, the polishing method according to another aspect of the present invention described below, and a method for producing a substrate according to still another aspect of the present invention described below are applied be used for polishing an object to be polished containing (a) the material having a silicon-nitrogen bond and (b) another material containing silicon.

In addition, it is more preferable that these polishing compositions be used for polishing an object to be polished containing (a) the material having a silicon-nitrogen bond and (b-1) the material having a silicon-oxygen bond or (b-2) the material having a silicon-silicon bond. Then, it is further preferable that these polishing compositions be used for polishing an object to be polished containing silicon nitride and silicon oxide (e.g., TEOS-SiO or the like) or polycrystalline silicon. Accordingly, it is more preferable that these polishing compositions be used for polishing an object to be polished containing (a) the material having a silicon-nitrogen bond and at least one of (b-1) the material having a silicon-oxygen bond and (b-2) the material having a silicon-silicon bond. Then, it is further preferable that these polishing compositions be used for polishing an object to be polished containing silicon nitride and at least one of silicon oxide (e.g., TEOS-SiO or the like) and polycrystalline silicon.

In addition, it is also more preferable that these polishing compositions be used for polishing an object to be polished containing (a) the material having a silicon-nitrogen bond and (b-1) the material having a silicon-oxygen bond, and (b-2) the material having a silicon-silicon bond. Then, it is also further preferable that these polishing compositions be used for polishing an object to be polished containing silicon nitride, silicon oxide (e.g., TEOS-SiO or the like), and polycrystalline silicon.

By applying these polishing compositions to an object to be polished as described above, it is possible to achieve a higher selectivity ratio and a higher effect of reducing the level difference between dissimilar materials while achieving a high polishing speed for a specific material.

Note that the object to be polished containing (a) the material having a silicon-nitrogen bond and (b) another material containing silicon may contain another material as necessary. As another material, a metal and the like are mentioned, but are not particularly limited thereto. As the metal, copper, aluminum, hafnium, cobalt, nickel, titanium, tungsten, and the like are mentioned, but are not particularly limited thereto.

Note that the object to be polished is preferably a substrate as a product form.

<Method for Producing Polishing Composition>

Another aspect of the present invention relates to a method for producing a polishing composition comprising mixing silica on the surface of which an organic acid is immobilized and a polyalkylene glycol, wherein

the molecular weight distribution of the polyalkylene glycol in terms of polyethylene glycol determined by gel permeation chromatography (GPC) has two or more peaks,

at least one peak of the molecular weight distribution is a peak of which the peak top molecular weight is 1,000 or more and 6,000 or less,

at least one peak of the molecular weight distribution is a peak of which the peak top molecular weight is 100 or more and 800 or less,

the polyalkylene glycol contains polyethylene glycol,

at least one of the peaks of which the peak top molecular weight is 1,000 or more and 6,000 or less is a peak derived from polyethylene glycol, and

a pH of the polishing composition is 3 or more and 6 or less. According to the present aspect, there may be provided a means that may achieve a markedly high selectivity ratio and a markedly high effect of reducing the level difference between dissimilar materials while achieving a high polishing speed for a specific material.

In addition, another aspect of the present invention relates to a method for producing a polishing composition comprising mixing

silica on the surface of which an organic acid is immobilized;

a polyethylene glycol of which the peak top molecular weight is 1,000 or more and 6,000 or less in a molecular weight distribution in terms of polyethylene glycol by gel permeation chromatography (GPC); and

a polyalkylene glycol of which the peak top molecular weight is 100 or more and 800 or less in a molecular weight distribution in terms of polyethylene glycol by gel permeation chromatography (GPC); wherein

a pH of the polishing composition is 3 or more and or less. The producing method according to the present aspect may become a preferred embodiment of the producing method according to the above aspect. According to the present aspect, there may be provided a means that may achieve a markedly high selectivity ratio and a markedly high effect of reducing the level difference between dissimilar materials while achieving a high polishing speed for a specific material.

In these aspects, details of the raw material, physical properties, and characteristics of the polishing composition to be produced, the object to be polished to which the polishing composition to be produced is applied, and the like are the same as those in the description of the polishing composition described above.

In addition, it can also be said that the production method according to these aspects is a preferred example of a production method for producing the polishing composition. Accordingly, the polishing composition produced by the production method according to these aspects is preferably a polishing composition containing:

silica on the surface of which an organic acid is immobilized; and

a polyalkylene glycol; wherein

the molecular weight distribution of the polyalkylene glycol in terms of polyethylene glycol determined by gel permeation chromatography (GPC) has two or more peaks,

at least one peak of the molecular weight distribution is a peak of which the peak top molecular weight is 1,000 or more and 6,000 or less,

at least one peak of the molecular weight distribution is a peak of which the peak top molecular weight is 100 or more and 800 or less,

the polyalkylene glycol contains polyethylene glycol,

at least one of the peaks of which the peak top molecular weight is 1,000 or more and 6,000 or less is a peak derived from polyethylene glycol, and

a pH of the polishing composition is 3 or more and 6 or less. In this case, the details and the like of the polishing composition to be produced, each component contained in the polishing composition, the object to be polished to which the polishing composition is applied, and the like are also the same as those in the description of the above polishing composition.

It is preferable that the mixing include mixing silica on the surface of which an organic acid is immobilized with two or more types of polyalkylene glycols different in the peak top molecular weight of the molecular weight distribution in terms of polyethylene glycol by gel permeation chromatography (GPC). Accordingly, in the case of mixing silica on the surface of which an organic acid is immobilized with a polyalkylene glycol in which at least one peak in the molecular weight distribution is a peak of which the peak top molecular weight is 1,000 or more and 6,000 or less, and at least one peak in the molecular weight distribution is a peak of which the peak top molecular weight is 100 or more and 800 or less, it is preferable that the mixing include mixing the polyalkylene glycol in which at least one peak in the molecular weight distribution is a peak of which the peak top molecular weight is 1,000 or more and 6,000 or less with the polyalkylene glycol in which at least one peak in the molecular weight distribution is a peak of which the peak top molecular weight is 100 or more and 800 or less. And, in this case, it is more preferable that the mixing include mixing the polyethylene glycol in which at least one peak in the molecular weight distribution is a peak of which the peak top molecular weight is 1,000 or more and 6,000 or less with the polyalkylene glycol in which at least one peak in the molecular weight distribution is a peak of which the peak top molecular weight is 100 or more and 800 or less.

In the mixing, the above-described polishing accelerator, the above-described level difference modifier, the above-described pH adjusting agent, the above-described dispersing medium, or the above-described another component may be further mixed, as necessary.

The temperature at which each component is mixed is, but not particularly limited to, preferably 10 to 40° C., and heating may be performed in order to increase the rate of dissolution.

In addition, the polishing composition according to an embodiment of the present invention, after a stock solution of the polishing composition is prepared by a method as described above, may be adjusted by diluting the stock solution (e.g., diluting to 10 times or more) using a diluent such as water.

<Polishing Method>

Another aspect of the present invention relates to a polishing method including: polishing an object to be polished using the above-described polishing composition; or producing a polishing composition by the above-described production method and polishing an object to be polished using the polishing composition.

It can also be said that the present aspect is an example of a polishing method using the above-described polishing composition or a polishing composition produced by the above-described production method. For this reason, the details and the like of the polishing composition, each component contained in the polishing composition, the object to be polished to which the polishing composition is applied, and the like are also the same as those in the description of the above polishing composition. In addition, details of the raw material, physical properties, and characteristics of the polishing composition to be produced, the object to be polished to which the polishing composition to be produced is applied, and the like are the same as those in the description of the polishing composition described above and the method for producing a polishing composition described above. Accordingly, as an example of a preferred embodiment, as described above, a polishing method in which an object to be polished includes a material having a silicon-nitrogen bond and another material containing silicon; a polishing method in which an object to be polished includes a material having a silicon-nitrogen bond and a material having a silicon-oxygen bond or a material having a silicon-silicon bond; a polishing method in which an object to be polished includes a material having a silicon-nitrogen bond and at least one of a material having a silicon-oxygen bond and a material having a silicon-silicon bond; a polishing method in which an object to be polished includes a material having a silicon-nitrogen bond, a material having a silicon-oxygen bond, and a material having a silicon-silicon bond; a polishing method in which an object to be polished includes silicon nitride and silicon oxide (e.g., TEOS-SiO or the like), or polycrystalline silicon; a polishing method in which an object to be polished includes silicon nitride, silicon oxide (e.g., TEOS-SiO or the like), and polycrystalline silicon; and the like are mentioned. Thus, it is possible to preferably use the polishing method according to an embodiment of the present invention for polishing a patterned wafer such as a polysilicon patterned wafer and the like.

In an embodiment of the present invention, on polishing the object to be polished using the polishing composition, it is possible to conduct the polishing using an apparatus and conditions used for normal polishing. As a common polishing apparatus, there are a single-side polishing apparatus and a double-side polishing apparatus. In a single-side polishing apparatus, a substrate is held using a holding jig called a carrier, and a surface plate to which a polishing pad is attached is pressed against a facing surface of the substrate to rotate the surface plate while a polishing composition is supplied from above, thereby polishing one side of a material to be polished (object to be polished). At this time, polishing is performed by physical action due to the friction between the polishing pad and the polishing composition and the object to be polished and chemical action caused by the polishing composition to the object to be polished. As the polishing pad, it is possible to use a porous body such as nonwoven fabric, polyurethane, swede, and the like without any particular limitation. It is preferable that the polishing pad be processed so as to cause a polishing liquid to accumulate.

As the polishing conditions, a polishing load, a rotation speed of a surface plate, a rotation speed of a carrier, a flow rate of a polishing composition, a polishing time, and the like are mentioned. These polishing conditions are not particularly limited, but for example, the polishing load is, per unit area of the substrate, preferably 0.1 psi or more to 10 psi or less (0.7 to 68.9 kPa, note that 1 psi=6894.76 Pa. The same applies hereinafter), more preferably 0.5 psi or more and 8 psi or less (3.4 to 55.1 kPa), and still more preferably 1 psi or more and 6 psi or less (6.9 to 41.4 kPa). In general, as the load becomes higher, the frictional force by abrasive grains becomes higher and the mechanical working force is enhanced. Therefore, the polishing speed increases. Within this range, a higher polishing speed is exerted, and it is possible to further suppress occurrence of breakage of the substrate due to a load and defects such as scratches on the surface. The rotation speed of a surface plate and the rotation speed of the carrier are preferably 10 to 500 rpm (0.2 to 8.3 s⁻¹, note that 60 rpm=1 s⁻¹. The same applies hereinafter). The amount of the polishing composition to be supplied may be an amount to be supplied (flow rate) with which the entire object to be polished is covered, and may be adjusted according to conditions such as the size of the object to be polished and the like. The method of supplying the polishing composition to the polishing pad is also not particularly limited, and for example, a method of continuously supplying the polishing composition via a pump or the like is adopted. In addition, the processing time is not particularly limited as long as the time causes a desired processing result to be obtained, but it is preferable to make the processing time shorter time due to a high polishing speed.

<Method for Producing Substrate>

Still another aspect of the present invention relates to a method for producing a substrate, comprising polishing an object to be polished by the above-described polishing method.

It can also be said that the present aspect is a preferable example of a method for producing a substrate, comprising a polishing method using the above-described polishing composition or a polishing composition produced by the above-described production method. For this reason, the details and the like of the polishing composition, each component contained in the polishing composition, the object to be polished to which the polishing composition is applied, and the like are also the same as those in the description of the above polishing composition. In addition, details of the raw material, physical properties, and characteristics of the polishing composition to be produced, the object to be polished to which the polishing composition to be produced is applied, and the like are the same as those in the description of the polishing composition described above and the method for producing a polishing composition described above. Then, the details of the polishing method are also the same as those in the description of the polishing method described above. Accordingly, as examples of preferred embodiments, a method of producing a substrate (polished substrate) in which the object to be polished is a substrate, a method of producing a semiconductor substrate (polished semiconductor substrate) in which the object to be polished is a semiconductor substrate, and the like are mentioned. Accordingly, it is possible to preferably use the method for producing a substrate according to an embodiment of the present invention for producing a patterned wafer such as a polysilicon patterned wafer and the like.

Although embodiments of the invention have been described in detail, the embodiments are illustrative and exemplary and not restrictive, and it is obvious that the scope of the invention is to be interpreted by the appended claims.

The present invention encompasses the following aspects and forms but is not limited thereto:

1. A polishing composition containing silica on a surface of which an organic acid is immobilized and a polyalkylene glycol, wherein

a molecular weight distribution of the polyalkylene glycol in terms of polyethylene glycol determined by gel permeation chromatography (GPC) has two or more peaks,

at least one peak of the molecular weight distribution is a peak of which a peak top molecular weight is 1,000 or more and 6,000 or less,

at least one peak of the molecular weight distribution is a peak of which a peak top molecular weight is 100 or more and 800 or less,

the polyalkylene glycol contains polyethylene glycol,

at least one of the peaks of which a peak top molecular weight is 1,000 or more and 6,000 or less is a peak derived from polyethylene glycol, and a pH of the polishing composition is 3 or more and 6 or less.

2. The polishing composition according to the above 1, wherein

at least one of the peaks of which the peak top molecular weight is 100 or more and 800 or less is a peak derived from polyethylene glycol, or

the polyalkylene glycol further contains polypropylene glycol or polybutylene glycol, and at least one of the peaks of which the peak top molecular weight is 100 or more and 800 or less is a peak derived from polypropylene glycol or polybutylene glycol.

3. The polishing composition according to the above 1 or the above 2, wherein the organic acid is a sulfonic acid or a carboxylic acid.

4. The polishing composition according to any of the above 1 to the above 3, wherein an average primary particle size of the silica on the surface of which an organic acid is immobilized is 10 nm or more and 50 nm or less.

5. The polishing composition according to any of the above 1 to the above 4, wherein the silica on the surface of which an organic acid is immobilized has an average secondary particle size of 20 nm or more and 100 nm or less.

6. The polishing composition according to any of the above 1 to the above 5, wherein, in the silica on the surface of which an organic acid is immobilized, silica before immobilization of the organic acid is colloidal silica produced by a sol gel method or a sodium silicate method.

7. The polishing composition according to any of the above 1 to the above 6, further containing a polishing accelerator.

8. The polishing composition according to any of the above 1 to the above 7, further containing a level difference modifier.

9. The polishing composition according to any of the above 1 to the above 8, further containing an acid.

10. The polishing composition according to any of the above 1 to the above 9, being used for polishing an object to be polished containing a material having a silicon-nitrogen bond and at least one of a material having a silicon-oxygen bond and a material having a silicon-silicon bond.

11. A method for producing a polishing composition comprising mixing

silica on a surface of which an organic acid is immobilized;

a polyethylene glycol of which a peak top molecular weight is 1,000 or more and 6,000 or less in a molecular weight distribution in terms of polyethylene glycol by gel permeation chromatography (GPC); and

a polyalkylene glycol of which a peak top molecular weight is 100 or more and 800 or less in a molecular weight distribution in terms of polyethylene glycol by gel permeation chromatography (GPC); wherein

a pH of the polishing composition is 3 or more and 6 or less.

12. A polishing method comprising:

polishing an object to be polished using the polishing composition according to any of the above 1 to above 10;

or,

producing a polishing composition according to the above 11 and polishing an object to be polished using the polishing composition.

13. The polishing method according to the above 12, wherein the object to be polished comprises a material having a silicon-nitrogen bond and at least one of a material having a silicon-oxygen bond and a material having a silicon-silicon bond.

14. A method for producing a polished substrate, wherein an object to be polished is a substrate, and the method comprises polishing the object to be polished by the polishing method according to the above 12 or the above 13.

### EXAMPLES

The present invention will be described in more detail with reference to the following Examples and Comparative Examples. However, the technical scope of the present invention is not limited only to the following examples. In the following Examples, unless otherwise specified, the operation was performed under the conditions of room temperature (25° C.)/relative humidity: 40 to 50% RH.

<Preparation of Polishing Composition>

Abrasive grains, polyalkylene glycol or ethylene glycol (EG), a pH adjusting agent, and other additives added as necessary were added to water as a solvent, and stirred and mixed to obtain each polishing composition (mixing temperature: about 25° C., mixing time: about 10 minutes). Here, the type and concentration (content, amount added) of each component used for preparing each polishing composition are shown in the following Table 1 and the following Table 2. In addition, the concentration (content, amount added) of the pH adjusting agent was set to an amount at which the obtained polishing composition achieved a pH described in the following Table 1 and the following Table 2.

Note that the pH of the polishing composition (liquid temperature: 25° C.) was confirmed with a pH meter (manufactured by HORIBA, Ltd., model number: LAQUA).

In addition, the zeta potential [mV] of the abrasive grains in the polishing composition was calculated by subjecting the polishing composition to ELS-Z2 manufactured by Otsuka Electronics Co., Ltd. to make measurement by a laser Doppler method (electrophoretic light scattering measurement method) using a flow cell at a measurement temperature of 25° C., and analyzing the obtained data by the Smoluchowski equation.

Details of the abrasive grains and polyalkylene glycols used for preparation of each polishing composition will be described below.

(Abrasive Grains)
Abrasive grains 1: silica on the surface of which sulfonic acid is immobilized (average primary particle size: 14 nm, average secondary particle size: 34 nm, cocoon-shaped, unmodified (before modification, before immobilization of organic acid) silica is colloidal silica produced by a sol-gel method);
Abrasive grains 2: silica on the surface of which sulfonic acid is immobilized (average primary particle size: 32 nm, average secondary particle size: 69 nm, cocoon-shaped, unmodified (before modification, before immobilization of organic acid) silica is colloidal silica produced by a sol-gel method);
Abrasive grains 3: silica on a surface of which sulfonic acid is immobilized (average primary particle size: 12 nm, average secondary particle size: 53 nm, cocoon-shaped, unmodified (before modification, before immobilization of organic acid) silica is colloidal silica produced by a sodium silicate method);
Abrasive grains A: unmodified silica (average primary particle size: 14 nm, average secondary particle size: 34 nm, cocoon-shaped, colloidal silica produced by a sol-gel method);

(Polyalkylene Glycol)
Polyethylene glycol 200 (PEG 200) (manufactured by FUJIFILM Wako Pure Chemical Corporation, product name: polyethylene glycol 200, polyethylene glycol having a peak of which the peak top molecular weight is 200);
Polyethylene glycol 600 (PEG 600) (manufactured by FUJIFILM Wako Pure Chemical Corporation, product name: polyethylene glycol 600, polyethylene glycol having a peak of which the peak top molecular weight is 600);
Polyethylene glycol 1000 (PEG 1000) (manufactured by FUJIFILM Wako Pure Chemical Corporation, product name: polyethylene glycol 1,000, polyethylene glycol having a peak of which the peak top molecular weight is 1,000);
Polyethylene glycol 1540 (PEG 1540) (manufactured by FUJIFILM Wako Pure Chemical Corporation, product name polyethylene glycol 1,540, polyethylene glycol having a peak of which the peak top molecular weight is 1,540);
Polyethylene glycol 2000 (PEG 2000) (manufactured by FUJIFILM Wako Pure Chemical Corporation, product name polyethylene glycol 2,000, polyethylene glycol having a peak of which the peak top molecular weight is 2,000);
Polyethylene glycol 4000 (PEG 4000) (manufactured by FUJIFILM Wako Pure Chemical Corporation, product name polyethylene glycol 4,000, polyethylene glycol having a peak of which the peak top molecular weight is 4,000);
Polyethylene glycol 6000 (PEG 6000) (manufactured by FUJIFILM Wako Pure Chemical Corporation, product name polyethylene glycol 6,000, polyethylene glycol having a peak of which the peak top molecular weight is 6,000);
Polyethylene glycol 8000 (PEG 8000) (manufactured by FUJIFILM Wako Pure Chemical Corporation, product name polyethylene glycol 8,000, polyethylene glycol having a peak of which the peak top molecular weight is 8,000);
Polyethylene glycol 10000 (PEG 10000) (manufactured by Alfa Aesar, product name: Polyethylene glycol 10,000, polyethylene glycol having a peak of which the peak top molecular weight is 10,000);
Polyethylene glycol 15000 (PEG 15000) (polyethylene glycol having a peak of which the peak top molecular weight is 15,000);
Polyethylene glycol 20,000 (PEG 20,000) (manufactured by FUJIFILM Wako Pure Chemical Corporation, product name polyethylene glycol 20,000, polyethylene glycol having a peak of which the peak top molecular weight is 20,000);
Polypropylene glycol 400 (PPG 400) (manufactured by FUJIFILM Wako Pure Chemical Corporation, product name: polypropylene glycol, diol type, 400, polypropylene glycol having a peak of which the peak top molecular weight is 400).

Note that, in the following Table 1 and the following Table 2, for example, “PEG 200/PEG 600” in the row of the type of “Peak top molecular weight: less than 1000 or EG” of the polishing composition 1 means that both PEG 200 and PEG 600 were used. In addition, “0.2/0.4” in the column of the Concentration (g/L) indicates that the concentration of PEG 200 is 0.2 g/L and the concentration of PEG 600 is 0.4 g/L. In addition, other combinations of types and combinations of concentrations are also denoted in the same manner.

<Evaluation of Molecular Weight Distribution, and Peak Top Molecular Weight in the Molecular Weight Distribution>

The molecular weight distribution and the peak top molecular weight in the molecular weight distribution of each of the above-described polyalkylene glycols used as the raw material were measured by gel permeation chromatography (GPC).

In addition, the molecular weight distribution of the polyalkylene glycol as a whole contained in the polishing composition in terms of polyethylene glycol and the peak top molecular weight of the peak in the molecular weight distribution were measured by gel permeation chromatography (GPC).

The measurement conditions for the molecular weight distribution and the peak top molecular weight of the polyalkylene glycols are as follows. In addition, polyethylene glycol was used as a standard substance.

GPC apparatus: manufactured by Shimadzu Corporation

Model: Prominence+ELSD detector (ELSD-LTII) Column: VP-ODS (manufactured by Shimadzu Corporation)

Mobile phase A: MeOH

B: 1% acetic acid aqueous solution

Flow rate: 1 mL/min

Detector: ELSD temp. 40° C., Gain 8, N2GAS 350 kPa

Oven temperature: 40° C.

Injection volume: 40 μl.

As a result of this measurement, each value of the peak top molecular weight of each peak in the molecular weight distribution of the polyalkylene glycol as a whole contained in the polishing composition was substantially the same as the value of the peak top molecular weight of the peak of the molecular weight distribution of the raw material polyalkylene glycol.

<Polishing Method>

Using each of the polishing compositions prepared above, the surface of each object to be polished was polished by the apparatus and the conditions described below. Here, the polishing conditions and the object to be polished are as follows.

(Polishing Conditions)

Polishing machine: CMP single-side polishing machine for 200 mm wafer

Pad: pad made of polyurethane

Pressure: 3 psi (about 20.7 kPa)

Surface plate rotation speed: 90 rpm (1.5 s⁻¹)

Flow rate of the polishing composition: 130 ml/min

Polishing time: 1 minute

Object to be polished: 200 mm wafer (Poly-Si, SiN, TEOS-SiO)

Polycrystalline silicon (Poly-Si): manufactured by a low pressure chemical vapor deposition (LPCVD) method: 5,000 Å in thickness

Silicon nitride (SiN): manufactured by a low pressure chemical vapor deposition (LPCVD) method: 3,500 Å in thickness

Silicon oxide (TEOS-SiO) derived from tetraethyl orthosilicate (TEOS): produced by a physical vapor deposition (PVD) method: 10,000 Å in thickness.

The polishing speed was evaluated by determining the film thicknesses before and after polishing by a light interference type film thickness measurement apparatus and dividing the difference thereof by the polishing time.

For the level difference, an 8-inch Poly-Si patterned wafer having the following configuration was polished, and the level difference of a portion at which the line-and-space was 0.25 μm/0.25 μm (hereinafter, also referred to as a wiring portion) from a portion around the wiring portion was measured using an atomic force microscope (AFM).

<<8-Inch Poly-Si Patterned Wafer>>

Specification

First layer: P-TEOS-SiO (plasma TEOS-SiO), 1,000 Å in thickness

Second layer: Poly-Si, 500 Å in thickness

Third layer: 854 pattern+etching

Fourth layer: SiN, 1,000 Å in thickness.

Here, erosion represents a phenomenon in which the Poly-Si portion of the wiring portion is recessed as compared with the portion around the wiring portion. In the erosion, the level difference between the Poly-Si portion of the wiring portion and the periphery of the wiring portion, after polishing was evaluated.

In addition, dishing represents a phenomenon in which the SiN portion of the wiring portion is recessed as compared with the portion around the wiring portion. In the dishing, the level difference between the SiN portion of the wiring portion and the periphery of the wiring portion, after polishing was evaluated.

In this evaluation, it was determined that a higher polishing speed of SiN was more preferable.

Additionally, in this evaluation, it was determined that the ratio of the polishing speed of SiN (Å/min) to the polishing speed of TEOS-SiO (Å/min) (the selectivity ratio of SiN to TEOS-SiO: SiN/TEOS-SiO) and the ratio of the polishing speed of SiN (Å/min) to the polishing speed of Poly-Si (Å/min) (the selectivity ratio of SiN to Poly-Si: SiN/Poly-Si) were each preferable as high as possible and that when the both were 25 or more, the composition was excellent in selectivity ratio.

In this evaluation, it was determined that the erosion and dishing are each preferable as small as possible and that the composition is excellent in the effect of reducing the level difference is excellent when the erosion is 45 Å or less and the dishing is 25 Å or less.

The formulation and physical properties of each polishing composition are shown in the following Table 1 and the following Table 2. The evaluation results of each polishing composition are shown in the following Table 3.

TABLE 1
Raw materials used for preparation of each polishing composition
and physical properties of each polishing composition

| | | | Polyalkylene glycol or ethylene glycol (EG) | | | |
|---|---|---|---|---|---|---|
| | | | Peak top molecular weight: | | Peak top molecular weight: | |
| | Abrasive grains | | 1000 or more | | less than 1000 or EG | |
| Polishing | | Concentration | | Concentration | | Concentration |
| composition | Type | [mass %] | Type | [g/L] | Type | [g/L] |
| 1 | Abrasive grains 1 | 3.0 | Not applicable | 0 | PEG200/PEG600 | 0.2/0.4 |
| 2 | Abrasive grains 1 | 3.0 | Not applicable | 0 | PEG200/PEG600 | 0.2/0.4 |
| 3 | Abrasive grains 1 | 3.0 | Not applicable | 0 | PEG200/PEG600 | 1.0/2.0 |
| 4 | Abrasive grains 1 | 3.0 | Not applicable | 0 | PEG200/PEG600 | 0.2/0.4 |
| 5 | Abrasive grains 1 | 3.0 | PEG1540 | 1.0 | PEG200/PEG600 | 0.2/0.4 |
| 6 | Abrasive grains 1 | 3.0 | PEG1540 | 1.0 | PEG200/PEG600 | 0.2/0.4 |
| 7 | Abrasive grains 1 | 3.0 | PEG1540 | 1.0 | PEG200/PEG600 | 0.2/0.4 |
| 8 | Abrasive grains 1 | 3.0 | PEG1540 | 1.0 | PEG200/PEG600 | 0.2/0.4 |
| 9 | Abrasive grains 1 | 3.0 | PEG1540 | 1.0 | PEG200/PEG600 | 0.2/0.4 |
| 10 | Abrasive grains 1 | 3.0 | PEG1540 | 1.0 | PEG200/PEG600 | 0.2/0.4 |
| 11 | Abrasive grains 1 | 3.0 | PEG1540 | 1.0 | PEG200/PEG600 | 0.2/0.4 |
| 12 | Abrasive grains 1 | 3.0 | PEG1000 | 1.0 | PEG200/PEG600 | 0.2/0.4 |
| 13 | Abrasive grains 1 | 3.0 | PEG2000 | 1.0 | PEG200/PEG600 | 0.2/0.4 |
| 14 | Abrasive grains 1 | 3.0 | PEG4000 | 1.0 | PEG200/PEG600 | 0.2/0.4 |
| 15 | Abrasive grains 1 | 3.0 | PEG6000 | 1.0 | PEG200/PEG600 | 0.2/0.4 |
| 16 | Abrasive grains 1 | 3.0 | PEG8000 | 1.0 | PEG200/PEG600 | 0.2/0.4 |
| 17 | Abrasive grains 1 | 3.0 | PEG10000 | 1.0 | PEG200/PEG600 | 0.2/0.4 |
| 18 | Abrasive grains 1 | 3.0 | PEG15000 | 1.0 | PEG200/PEG600 | 0.2/0.4 |
| 19 | Abrasive grains 1 | 3.0 | PEG20000 | 1.0 | PEG200/PEG600 | 0.2/0.4 |

| | Level | | | | | |
|---|---|---|---|---|---|---|
| | difference | SiN polishing | | Physical properties | | |
| | modifier (m- | accelerator | | | Zeta | |
| | xylene | (N-methyl-D- | pH | | potential of | |
| | sulfonic acid) | glucamine) | Adjusting | | abrasive | |
| Polishing | Concentration | Concentration | agent | | grains | |
| composition | [g/L] | [g/L] | Type | pH | [mV] | Remarks |
| 1 | 1.0 | 2.5 | Maleic acid | 2.5 | −40 | Comparative Example |
| 2 | 1.0 | 2.5 | Maleic acid | 3.0 | −42 | Comparative Example |
| 3 | 1.0 | 2.5 | Maleic acid | 4.5 | −42 | Comparative Example |
| 4 | 1.0 | 2.5 | Maleic acid | 4.5 | −42 | Comparative Example |
| 5 | 1.0 | 2.5 | Maleic acid | 4.5 | −42 | Present invention |
| 6 | 1.0 | 2.5 | Maleic acid | 2.5 | −40 | Comparative Example |
| 7 | 1.0 | 2.5 | Maleic acid | 3.0 | −40 | Present invention |
| 8 | 1.0 | 2.5 | Maleic acid | 3.5 | −41 | Present invention |
| 9 | 1.0 | 2.5 | Maleic acid | 5.7 | −44 | Present invention |
| 10 | 1.0 | 2.5 | Maleic acid | 7.0 | −44 | Comparative Example |
| 11 | 0 | 2.5 | Maleic acid | 4.5 | −43 | Present invention |
| 12 | 1.0 | 2.5 | Maleic acid | 4.5 | −42 | Present invention |
| 13 | 1.0 | 2.5 | Maleic acid | 4.5 | −42 | Present invention |
| 14 | 1.0 | 2.5 | Maleic acid | 4.5 | −42 | Present invention |
| 15 | 1.0 | 2.5 | Maleic acid | 4.5 | −42 | Present invention |
| 16 | 1.0 | 2.5 | Maleic acid | 4.5 | −42 | Comparative Example |
| 17 | 1.0 | 2.5 | Maleic acid | 4.5 | −42 | Comparative Example |
| 18 | 1.0 | 2.5 | Maleic acid | 4.5 | −42 | Comparative Example |
| 19 | 1.0 | 2.5 | Maleic acid | 4.5 | −42 | Comparative Example |

TABLE 2
Raw materials used for preparation of each polishing composition
and physical properties of each polishing composition

| | | | Polyalkylene glycol or ethylene glycol (EG) | | | |
|---|---|---|---|---|---|---|
| | | | Peak top molecular weight: | | Peak top molecular weight: | |
| | Abrasive grains | | 1000 or more | | less than 1000 or EG | |
| Polishing | | Concentration | | Concentration | | Concentration |
| composition | Type | [mass %] | Type | [g/L] | Type | [g/L] |
| 20 | Abrasive grains 1 | 3.0 | PEG2000 | 1.5 | PEG200/PEG600 | 0.2/0.4 |
| 21 | Abrasive grains 1 | 3.0 | PEG2000 | 2.0 | PEG200/PEG600 | 0.2/0.4 |
| 22 | Abrasive grains 1 | 3.0 | PEG1540 | 1.0 | Not applicable | 0 |
| 23 | Abrasive grains 1 | 3.0 | PEG1540 | 1.0 | PEG600 | 0.4 |
| 24 | Abrasive grains 1 | 3.0 | PEG1540 | 1.0 | PEG200 | 0.2 |
| 25 | Abrasive grains 1 | 3.0 | PEG1540 | 1.0 | PEG200/PEG600 | 1.0/2.0 |
| 26 | Abrasive grains 1 | 3.0 | PEG1540 | 1.0 | PPG400 | 0.6 |
| 27 | Abrasive grains 1 | 3.0 | PEG1540 | 1.0 | EG | 0.6 |
| 28 | Abrasive grains A | 3.0 | PEG1540 | 1.0 | PEG200/PEG600 | 0.2/0.4 |
| 29 | Abrasive grains 2 | 3.0 | PEG1540 | 1.0 | PEG200/PEG600 | 0.2/0.4 |
| 30 | Abrasive grains 3 | 3.0 | PEG1540 | 1.0 | PEG200/PEG600 | 0.2/0.4 |
| 31 | Abrasive grains 1 | 3.0 | PEG1540 | 1.0 | PEG200/PEG600 | 0.2/0.4 |
| 32 | Abrasive grains 1 | 3.0 | PEG1540 | 1.0 | PEG200/PEG600 | 0.2/0.4 |

| | Level | | | | | |
|---|---|---|---|---|---|---|
| | difference | SiN polishing | | Physical properties | | |
| | modifier (m- | accelerator | | | Zeta | |
| | xylene | (N-methyl-D- | pH | | potential of | |
| | sulfonic acid) | glucamine) | Adjusting | | abrasive | |
| Polishing | Concentration | Concentration | agent | | grains | |
| composition | [g/L] | [g/L] | Type | pH | [mV] | Remarks |
| 20 | 1.0 | 2.5 | Maleic acid | 4.5 | −42 | Present invention |
| 21 | 1.0 | 2.5 | Maleic acid | 4.5 | −42 | Present invention |
| 22 | 1.0 | 2.5 | Maleic acid | 4.5 | −42 | Comparative Example |
| 23 | 1.0 | 2.5 | Maleic acid | 4.5 | −42 | Present invention |
| 24 | 1.0 | 2.5 | Maleic acid | 4.5 | −42 | Present invention |
| 25 | 1.0 | 2.5 | Maleic acid | 4.5 | −42 | Present invention |
| 26 | 1.0 | 2.5 | Maleic acid | 4.5 | −42 | Present invention |
| 27 | 1.0 | 2.5 | Maleic acid | 4.5 | −42 | Comparative Example |
| 28 | 1.0 | 2.5 | Maleic acid | 4.5 | +5 | Comparative Example |
| 29 | 1.0 | 2.5 | Maleic acid | 4.5 | −38 | Present invention |
| 30 | 1.0 | 2.5 | Maleic acid | 4.5 | −32 | Present invention |
| 31 | 1.0 | 2.5 | Hydroxyisobutyric | 4.5 | −42 | Present invention |
| | | | acid | | | |
| 32 | 1.0 | 2.5 | nitric acid | 4.5 | −42 | Present invention |

TABLE 3
Evaluation results of each polishing composition

| | | | | | | Effect of reducing | | |
|---|---|---|---|---|---|---|---|---|
| | Polishing speed | | | Selectivity ratio | | the level difference | | |
| Polishing | [Å/min] | | | SiN/ | SiN/ | Erosion | Dishing | |
| composition | TEOS-SiO | Poly-si | SiN | TEOS-SiO | Poly-Si | [Å] | [Å] | Remarks |
| 1 | 36 | 28 | 867 | 24.09 | 30.99 | 80 | 20 | Comparative Example |
| 2 | 33 | 36 | 761 | 23.07 | 21.01 | 53 | 22 | Comparative Example |
| 3 | 28 | 42 | 692 | 24.54 | 16.41 | 31 | 29 | Comparative Example |
| 4 | 27 | 49 | 690 | 26.04 | 14.23 | 30 | 35 | Comparative Example |
| 5 | 22 | 23 | 681 | 31.62 | 29.73 | 29 | 19 | Present invention |
| 6 | 38 | 12 | 871 | 22.66 | 73.32 | 78 | 19 | Comparative Example |
| 7 | 25 | 15 | 764 | 30.58 | 49.71 | 44 | 21 | Present invention |
| 8 | 23 | 21 | 720 | 31.32 | 33.65 | 35 | 20 | Present invention |
| 9 | 20 | 26 | 675 | 34.30 | 25.96 | 27 | 23 | Present invention |
| 10 | 36 | 421 | 52 | 1.44 | 0.12 | 30 | 33 | Comparative Example |
| 11 | 24 | 25 | 721 | 30.04 | 28.84 | 32 | 22 | Present invention |
| 12 | 19 | 26 | 673 | 35.42 | 25.88 | 28 | 21 | Present invention |
| 13 | 21 | 20 | 643 | 31.21 | 32.65 | 31 | 18 | Present invention |
| 14 | 19 | 23 | 599 | 32.39 | 26.14 | 32 | 20 | Present invention |
| 15 | 18 | 20 | 604 | 34.19 | 30.20 | 33 | 21 | Present invention |
| 16 | 23 | 24 | 585 | 25.43 | 24.38 | 36 | 23 | Comparative Example |
| 17 | 22 | 32 | 593 | 26.95 | 18.53 | 37 | 26 | Comparative Example |
| 18 | 29 | 37 | 586 | 20.21 | 15.84 | 38 | 27 | Comparative Example |
| 19 | 27 | 40 | 579 | 21.44 | 14.48 | 39 | 29 | Comparative Example |
| 20 | 21 | 24 | 632 | 30.66 | 26.06 | 30 | 19 | Present invention |
| 21 | 17 | 20 | 618 | 36.48 | 31.35 | 31 | 20 | Present invention |
| 22 | 23 | 23 | 682 | 29.65 | 29.78 | 46 | 27 | Comparative Example |
| 23 | 22 | 23 | 681 | 31.62 | 29.73 | 29 | 21 | Present invention |
| 24 | 23 | 23 | 683 | 29.70 | 29.82 | 28 | 22 | Present invention |
| 25 | 24 | 22 | 685 | 28.54 | 31.14 | 28 | 20 | Present invention |
| 26 | 22 | 25 | 679 | 30.86 | 27.16 | 31 | 22 | Present invention |
| 27 | 23 | 25 | 681 | 29.61 | 27.24 | 47 | 26 | Comparative Example |
| 28 | 58 | 46 | 124 | 2.14 | 2.70 | 51 | 22 | Comparative Example |
| 29 | 27 | 25 | 676 | 25.04 | 27.04 | 32 | 21 | Present invention |
| 30 | 12 | 23 | 598 | 49.83 | 26.00 | 23 | 20 | Present invention |
| 31 | 22 | 24 | 685 | 31.14 | 28.54 | 30 | 19 | Present invention |
| 32 | 24 | 23 | 690 | 28.75 | 30.00 | 31 | 19 | Present invention |

As shown in the above Table 1 to the above Table 3, it was confirmed that the polishing compositions according to Comparative Examples corresponds to at least one of the polishing speed of silicon nitride (SiN) being low, the selectivity ratio of SiN to TEOS-SiO being low, the selectivity ratio of SiN to Poly-Si being low, the erosion being large, and, the dishing is large and that a sufficient effect cannot be obtained.

On the other hand, it has been confirmed that, in the polishing compositions according to the present invention, the polishing speed of silicon nitride (SiN) is high, the selectivity ratio of SiN to TEOS-SiO and the selectivity ratio of SiN to Poly-Si are markedly high, the erosion and dishing are extremely small, and the compositions are markedly excellent in the effect of reducing the level difference.

The present application is based on Japanese Patent Application No. 2020-163619 filed on Sep. 29, 2020, and Japanese Patent Application No. 2021-118843 filed on Jul. 19, 2021, the disclosures of which are incorporated herein by reference in its entirety.

What is claimed is:

1. A polishing composition containing silica on a surface of which an organic acid is immobilized and a polyalkylene glycol, wherein
a molecular weight distribution of the polyalkylene glycol in terms of polyethylene glycol determined by gel permeation chromatography (GPC) has two or more peaks,
at least one peak of the molecular weight distribution is a peak of which a peak top molecular weight is 1,000 or more and 6,000 or less,
at least one peak of the molecular weight distribution is a peak of which a peak top molecular weight is 100 or more and 800 or less,
the polyalkylene glycol contains polyethylene glycol,
at least one of the peaks of which a peak top molecular weight is 1,000 or more and 6,000 or less is a peak derived from polyethylene glycol, and
a pH of the polishing composition is 3 or more and 6 or less.

2. The polishing composition according to claim 1, wherein
at least one of the peaks of which the peak top molecular weight is 100 or more and 800 or less is a peak derived from polyethylene glycol, or
the polyalkylene glycol further contains polypropylene glycol or polybutylene glycol, and at least one of the peaks of which the peak top molecular weight is 100 or more and 800 or less is a peak derived from polypropylene glycol or polybutylene glycol.

3. The polishing composition according to claim 1, wherein the organic acid is a sulfonic acid or a carboxylic acid.

4. The polishing composition according to claim 1, wherein an average primary particle size of the silica on the surface of which an organic acid is immobilized is 10 nm or more and 50 nm or less.

5. The polishing composition according to claim 1, wherein an average secondary particle size of the silica on the surface of which an organic acid is immobilized is 20 nm or more and 100 nm or less.

6. The polishing composition according to claim 1, wherein, in the silica on the surface of which an organic acid is immobilized, silica before immobilization of the organic acid is colloidal silica produced by a sol gel method or a sodium silicate method.

7. The polishing composition according to claim 1, further containing a polishing accelerator.

8. The polishing composition according to claim 1 further containing a level difference modifier.

9. The polishing composition according to claim 1 further containing an acid.

10. The polishing composition according to claim 1 being used for polishing an object to be polished containing a material having a silicon-nitrogen bond and at least one of a material having a silicon-oxygen bond and a material having a silicon-silicon bond.

11. A method for producing a polishing composition comprising mixing
silica on a surface of which an organic acid is immobilized;
a polyethylene glycol of which a peak top molecular weight is 1,000 or more and 6,000 or less in a molecular weight distribution in terms of polyethylene glycol by gel permeation chromatography (GPC); and
a polyalkylene glycol of which a peak top molecular weight is 100 or more and 800 or less in a molecular weight distribution in terms of polyethylene glycol by gel permeation chromatography (GPC); wherein
a pH of the polishing composition is 3 or more and 6 or less.

12. A polishing method of polishing an object to be polished using the polishing composition according to claim 1.

13. The polishing method according to claim 12, wherein the object to be polished comprises a material having a silicon-nitrogen bond and at least one of a material having a silicon-oxygen bond and a material having a silicon-silicon bond.

14. A method for producing a polished substrate, wherein an object to be polished is a substrate, and the method comprises polishing the object to be polished by the polishing method according to claim 12.
